(19) United States
(12) Patent Application Publication
(10) Pub. No.: US 2009/0052152 A1
(43) Pub. Date: Feb. 26, 2009

(54) Electronic Sensor

(75) Inventors: Karlheinz ULLRICH, Gross-Umstadt (DE); Karlheinz WIENAND, Aschaffenburg (DE)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: HERAEUS SENSOR TECHNOLOGY GMBH, Hanau (DE)

(21) Appl. No.: 12/193,799

(22) Filed: Aug. 19, 2008

(30) Foreign Application Priority Data
Aug. 20, 2007 (DE) 102007039280.1-52

(51) Int. Cl. H05K 7/02

(52) U.S. Cl. 361/811

(57) ABSTRACT

A high-temperature platform chip has at least three electrodes on an electrically insulating substrate constructed as a heating plate with a heat conductor on the back side.

### BACKGROUND OF THE INVENTION

The present invention relates to a high-temperature platform chip having a plurality of electrodes and a multi-metal-oxide sensor produced from these electrodes.

International patent application Publication No. WO 03/087811 A1 discloses sensor arrays for the simultaneous analysis of two or more components of a mixture, in particular a combustion gas. For this purpose, various electrodes are coated with various sensitive materials to form an array chip.

### BRIEF SUMMARY OF THE INVENTION

An object of the present invention is to improve the sensitivity and measurement accuracy of such sensors for the high-temperature range.

According to the invention, it was recognized for this purpose that the reproducibility is improved by heating the chip on the back side. For further increasing the reproducibility, the geometry of the heat conductor arrangement, as well as the arrangement of the sensitive layers, are optimized.

The arrangement of the heat conductor on the back side of the substrate effects a uniform heating of the front side, on which the sensitive elements are heated uniformly. The substrate serves as a heating plate. The chip equipped in this way is, according to the invention, a high-temperature chip, i.e., for use at temperatures above 400° C., preferably 500° C. to 850° C., and most preferably 630° C. to 750° C. This involves a platform chip, i.e., the chip is a platform for the application of sensitive elements, particularly metal-oxide sensors.

Such a high-temperature platform chip has, according to the invention, three electrodes on an electrically insulating substrate formed as a heating plate with a heat conductor on the back side. The heat conductor is constructed as a chip or covered with a passivation layer, so that for a defined use it is protected from the atmosphere.

Platinum or platinum-rhodium electrodes have proven useful as electrodes on the substrate.

Plates made from an inorganic oxide, for example Al₂O₃, have proven useful as the substrate.

The heat conductor is preferably made from platinum or a platinum-rhodium alloy. The electrodes and also the heat conductor can be fabricated using thick-film technology, but are preferably fabricated using thin-film technology.

An additional temperature measurement resistor is preferably fabricated using thin-film technology. The temperature measurement resistor can be fabricated together with the electrodes in a structuring step. It has also proven useful to mount temperature measurement resistor chips, created using thin-film technology, with their conductor tracks on contact fields provided therefor next to the electrodes on the top surface of the substrate.

It is further preferred to maintain the temperature difference among the electrodes at less than 10° C., preferably less than 5° C., in which the electrodes are arranged on sections of the substrate that have approximately the same temperatures when heating with the heat conductor to 600° C. to 800° C.

A metal-oxide sensor array chip can be fabricated from the high-temperature platform chip by application of a metal-oxide sensor array on the electrodes. For this metal-oxide sensor array chip, analogous to the platform chip, the metal-oxide sensor array elements are arranged in such a way that, when heating the heating plate with heating conductors on the back side to 600° C. to 800° C., particularly 630° C. to 750° C., the temperature difference among the metal-oxide sensor array elements is less than 10° C., preferably less than 5° C.

The temperature matching according to the invention optimizes the measurement accuracy and reliability of the array.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a longitudinal plan view of the sensor side of a sensor according to one embodiment of the present invention;

FIG. 2 is detailed plan view of the sensor side of the tip of the sensor shown in FIG. 1;

FIG. 3 is a plot of the heat distribution on the sensor side of the sensor tip shown in FIGS. 1 and 2; and

FIG. 4 is an exploded, perspective view showing the layers of a platform chip according to one embodiment of the invention.

### DETAILED DESCRIPTION OF THE INVENTION

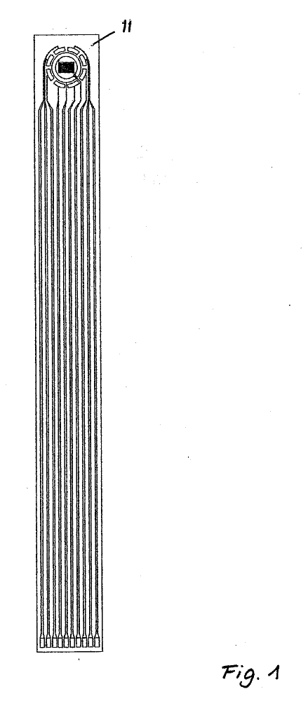

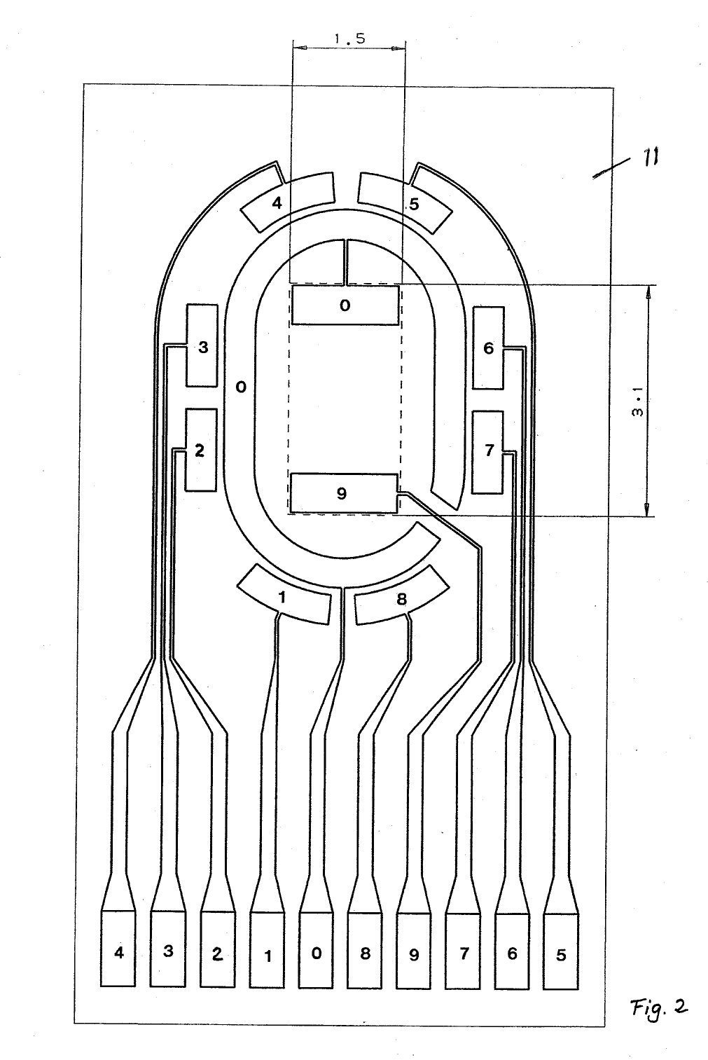

The sensor according to FIGS. 1 to 3 is made from a ceramic strip 11, on which elongated conductor tracks are arranged. The conductor tracks end on the connection side of the sensor with wider sections in the form of contact fields (pads). In the region of the measurement tip, the conductor tracks are widened to form electrodes. The chip is constructed as a platform chip, whose electrodes 1 to 8 are provided for a coating array, whose coatings connect the electrodes 1 to 8 to the counter electrode 0. The electrode 9 is provided for the arrangement of a temperature-sensitive thin-film chip, whose circuit is likewise closed by the counter electrode 0. The pattern of electrodes, conductor tracks, and pads is generated by structuring a metallic thin film or by screen printing of a metal paste.

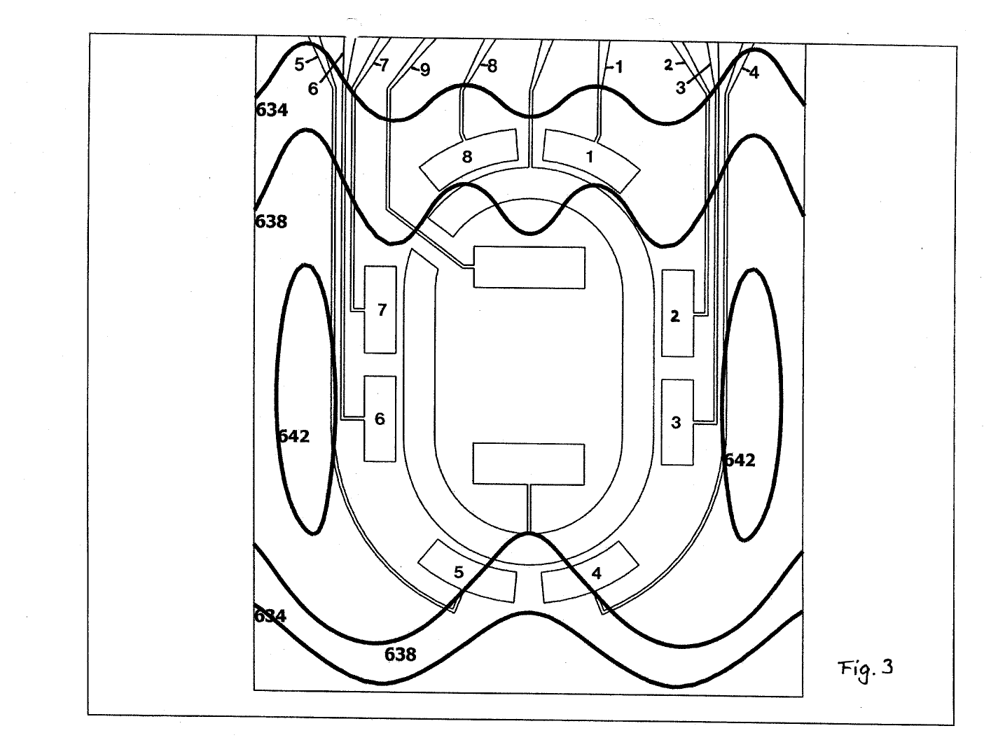

FIG. 3 shows the heat distribution on the electrode side of the chip at 640° C. The electrodes are here arranged on the chip in such a way that the electrode surfaces have the smallest possible temperature difference.

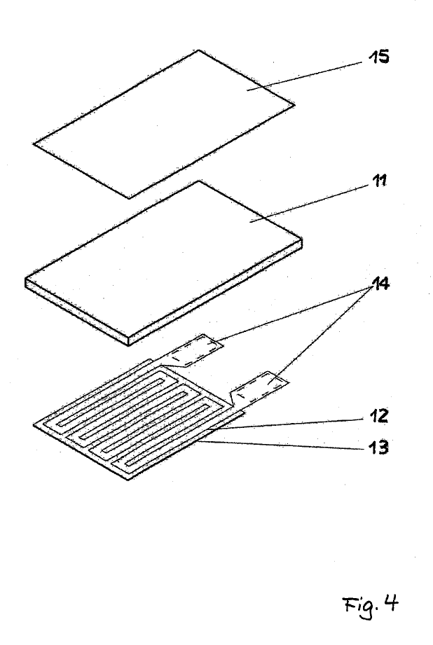

On the back side, the chip has a heat conductor in the region of the measurement tip. The heat conductor is constructed for a uniform heating of the chip. According to FIG. 4, the heat conductor is constructed as a ceramic chip, particularly with a conductor track deposited using thin-film technology or on the back side as a conductor track 12 on the ceramic strip and covered with a passivation layer 13.

The heat conductor 12 is connected electrically by contact pads 14. On the heating plate made of the ceramic strip 11 with a heater, a metal layer 15 is deposited and structured to form the pattern according to FIGS. 1 to 3.

A preferred embodiment is represented by a combined part. On a heating plate having a heat conductor on the back side, only supply lines are applied on the front side preferably by screen printing thick-film technology. The electrodes with the integrated temperature measurement resistor are executed on a separate carrier by platinum thin-film technology. This part allows the metal oxide application in a separate operation step, so that afterwards the gas sensor part with integrated temperature sensor is joined on the back side of the heating plate, and the thin-film conductor tracks can be connected by thin wires (bonding wires) to the supply lines of the carrier. These wire connections are finally electrically and mechanically sealed with glass.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

I/we claim:

1. A high-temperature platform chip, comprising at least three electrodes of arranged on an electrically insulating substrate, the substrate having a form of a heating plate with a heat conductor on its back side.

2. The high-temperature platform chip according to claim 1, wherein the electrodes are arranged in such a way that when the heating plate is heated by a heater on the back side to 600° C. to 800° C., a temperature difference among the electrodes equals less than 10° C.

3. The high-temperature platform chip according to claim 1, wherein the platform chip has a temperature measurement resistor.

4. The high-temperature platform chip according to claim 3, wherein a chip is arranged on the heating plate, and the electrodes and optionally the temperature measurement resistor are applied to the chip in thin-film technology (chip-on-board technology).

5. A high-temperature multi-metal-oxide sensor chip having a multi-metal-oxide sensor arrangement, the chip comprising at least three electrodes arranged as metal oxide sensor layers on an electrically insulating substrate in a form of a heating plate with a heat conductor on its back side.

6. The high-temperature multi-metal-oxide sensor chip according to claim 5, wherein, when heating the heating plate by a heat conductor on the back side to 700° C. to 800° C., a temperature difference among the metal oxide sensor layers equals less than 10° C.
